(19) United States
(12) Patent Application Publication
(10) Pub. No.: US 2024/0429118 A1
(43) Pub. Date: Dec. 26, 2024

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Keisuke TOKUBUCHI, Yokkaichi Mie (JP)

(73) Assignee: Kioxia Corporation, Tokyo (JP)

(21) Appl. No.: 18/679,697

(22) Filed: May 31, 2024

(30) Foreign Application Priority Data
Jun. 20, 2023 (JP) 2023-100747

(51) Int. Cl. H01L 23/31; H01L 21/56; H01L 21/762; H01L 23/00; H01L 23/29; H01L 23/498; H01L 23/528; H01L 25/065

(52) U.S. Cl. CPC H01L 23/3128; H01L 21/56; H01L 21/76224; H01L 23/291; H01L 23/49833; H01L 23/528; H01L 23/5283; H01L 25/0657; H01L 24/32; H01L 24/48; H01L 24/73; H01L 2224/32145; H01L 2224/32225; H01L 2224/48145; H01L 2224/48225; H01L 2224/73265; H01L 2225/06506; H01L 2225/0651; H01L 2225/06562; H01L 2924/1434; H01L 2924/1815

(57) ABSTRACT

A semiconductor device includes: a first substrate; a second substrate provided above the first substrate, the second substrate being smaller in area than the first substrate when the second substrate is viewed from above; a first layer provided between the first substrate and the second substrate and having a first conductive pad; a second layer provided between the first layer and the second substrate and having a second conductive pad bonded to the first conductive pad; and an insulator covering each of at least one side surface of the first substrate and at least one side surface of the second substrate.

### CROSS-REFERENCE TO RELATED APPLICATION

This application is based upon and claims the benefit of priority from Japanese Patent Application No. 2023-100747, filed on Jun. 20, 2023; the entire contents of which are incorporated herein by reference.

### FIELD

Embodiments relate to a semiconductor device and a method of manufacturing a semiconductor device.

### BACKGROUND

In recent years, known examples of a semiconductor device include a semiconductor memory device which can be formed by bonding a first semiconductor substrate having a memory cell array and a second semiconductor substrate having a peripheral circuit.

### BRIEF DESCRIPTION OF THE DRAWINGS

FIG. 1 is a top schematic view illustrating an example structure of a semiconductor chip.

FIG. 2 is a cross-sectional schematic view illustrating the example structure of the semiconductor chip.

FIG. 3 is a cross-sectional schematic view illustrating the example structure of the semiconductor chip.

FIG. 4 is a cross-sectional schematic view illustrating the example structure of the semiconductor chip.

FIG. 5 is an X-Z cross-sectional schematic view for explaining an example structure of a memory pillar MP.

FIG. 6 is a schematic view for explaining an example method of manufacturing the semiconductor chip.

FIG. 7 is a schematic view for explaining the example method of manufacturing the semiconductor chip.

FIG. 8 is a schematic view for explaining the example method of manufacturing the semiconductor chip.

FIG. 9 is a schematic view for explaining the example method of manufacturing the semiconductor chip.

FIG. 10 is a schematic view for explaining the example method of manufacturing the semiconductor chip.

FIG. 11 is a schematic view for explaining the example method of manufacturing the semiconductor chip.

FIG. 12 is a schematic view for explaining the example method of manufacturing the semiconductor chip.

FIG. 13 is a schematic view for explaining the example method of manufacturing the semiconductor chip.

FIG. 14 is a schematic view for explaining the example method of manufacturing the semiconductor chip.

FIG. 15 is a schematic view for explaining the example method of manufacturing the semiconductor chip.

FIG. 16 is a schematic view for explaining the example method of manufacturing the semiconductor chip.

FIG. 17 is a schematic view for explaining a difference between a case of forming a groove D and a case of not forming the groove D.

FIG. 18 is a schematic view for explaining the difference between the case of forming the groove D and the case of not forming the groove D.

FIG. 19 is a schematic view illustrating an example structure of a semiconductor package.

### DETAILED DESCRIPTION

A semiconductor device includes: a first substrate; a second substrate provided above the first substrate, the second substrate being smaller in area than the first substrate when the second substrate is viewed from above; a first layer provided between the first substrate and the second substrate and having a first conductive pad; a second layer provided between the first layer and the second substrate and having a second conductive pad bonded to the first conductive pad; and an insulator covering each of at least one side surface of the first substrate and at least one side surface of the second substrate.

Embodiments will be hereinafter explained with reference to the drawings. A relation between the thickness and planar dimension of each of components illustrated in the drawings, a thickness ratio among the components, and so on may be different from actual ones. In the embodiments, substantially the same components are denoted by the same reference signs and an explanation thereof is omitted where appropriate.

### Example Structure of a Semiconductor Chip

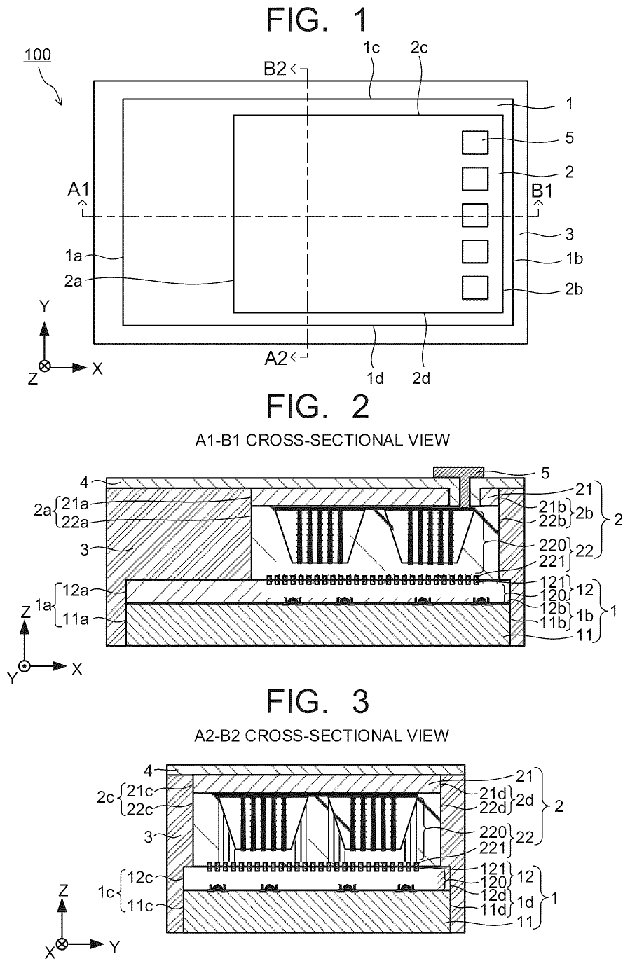

An example of a semiconductor chip will be explained as an example of a semiconductor device in an embodiment. FIG. 1 is a top schematic view illustrating an example structure of the semiconductor chip. FIG. 2 is a cross-sectional schematic view illustrating the example structure of the semiconductor chip and illustrates an example of a cross section taken along a line segment A1-B1 of a semiconductor chip 100 in FIG. 1. FIG. 3 is a cross-sectional schematic view illustrating the example structure of the semiconductor chip and illustrates an example of a cross section taken along a line segment A2-B2 of the semiconductor chip 100 in FIG. 1. FIG. 1, FIG. 2, and FIG. 3 indicate an X-axis, a Y-axis, and a Z-axis. The X-axis, the Y-axis, and the Z-axis perpendicularly intersect with one another. The Z-axis is along a thickness direction of the semiconductor chip 100. FIG. 1 illustrates an X-Y plane including the X-axis and the Y-axis. FIG. 2 illustrates an X-Z cross section including the X-axis and the Z-axis. FIG. 3 illustrates a Y-Z cross section including the Y-axis and the Z-axis. The above example structure is an example, and the example structure of the semiconductor chip in the embodiment is not limited to this example structure.

The semiconductor chip 100 has a semiconductor substrate 1, a semiconductor substrate 2, an insulator 3, an insulating layer 4, and an electric conductor 5. Examples of the semiconductor chip 100 include a memory chip. Examples of the memory chip usable to the semiconductor chip 100, include a nonvolatile memory chip and a volatile memory chip. Examples of the nonvolatile memory chip usable to the semiconductor chip 100, include a NAND memory chip, a phase change memory chip, a resistance change memory chip, a ferroelectric memory chip, and a magnetic memory chip. Examples of the volatile memory chip usable to the semiconductor chip 100, include a dynamic random access memory (DRAM) chip.

The semiconductor substrate 1 has a substrate 11 and a layer 12. The semiconductor substrate 1 includes, for example, a semiconductor chip having a peripheral circuit. The semiconductor substrate 1 has a side 1a, a side 1b, a side 1c, and a side 1d. The side 1a extends in a direction (for example, a Y-axis direction) intersecting with a Z-axis direction. The side 1b is provided on the opposite side across the semiconductor substrate 1 from the side 1a and extends in the direction (for example, the Y-axis direction) intersecting with the Z-axis direction. The side 1c extends in a direction (for example, an X-axis direction) intersecting with the side 1a. The side 1d is provided on the opposite side across the semiconductor substrate 1 from the side 1c and extends in the direction (for example, the X-axis direction) intersecting with the side 1a.

The side 1a includes a side surface 11a of the substrate 11 and a side surface 12a of the layer 12. The side 1b includes a side surface 11b of the substrate 11 and a side surface 12b of the layer 12. The side 1c includes a side surface 11c of the substrate 11 and a side surface 12c of the layer 12. The side 1d includes a side surface 11d of the substrate 11 and a side surface 12d of the layer 12. For example, the side surfaces 12a, 12b, 12c, 12d extend to be flush with the side surfaces 11a, 11b, 11c, 11d, respectively.

Examples of the substrate 11 include a semiconductor wafer such as a silicon substrate.

The layer 12 is provided on the surface of the substrate 11. The layer 12 is arranged between the substrate 11 and the semiconductor substrate 2. The layer 12 has a peripheral circuit 120 and a conductive pad 121.

The semiconductor substrate 2 is provided on a part of the semiconductor substrate 1. In the X-Y plane, the plane area of the semiconductor substrate 2 is smaller than the plane area of the semiconductor substrate 1 when the semiconductor substrate 2 is viewed from above. In other words, when the semiconductor substrate 2 is viewed in the Z-direction, the plane area of the semiconductor substrate 2 is smaller than the plane area of the semiconductor substrate 1. The semiconductor substrate 2 has a substrate 21 and a layer 22. The semiconductor substrate 2 includes a semiconductor chip having a memory cell array, for example. The semiconductor substrate 2 includes a side surface 2a, a side surface 2b, a side surface 2c, and a side surface 2d. The side surface 2a extends in a direction (for example, the Y-axis direction) intersecting with the Z-axis direction. The side surface 2b is provided on the opposite side across the semiconductor substrate 2 from the side surface 2a and extends in a direction (for example, the Y-axis direction) intersecting with the Z-axis direction. The side surface 2c extends in a direction (for example, the X-axis direction) intersecting with the side surface 2a. The side surface 2d is provided on the opposite side across the semiconductor substrate 2 from the side surface 2c and extends in a direction (for example, the X-axis direction) intersecting with the side surface 2a. The number of the semiconductor substrates 2 and the number of the memory cell arrays are not limited to the numbers illustrated in FIG. 1 to FIG. 3.

The side surface 2a includes a side surface 21a of the substrate 21 and a side surface 22a of the layer 22. The side surface 2b includes a side surface 21b of the substrate 21 and a side surface 22b of the layer 22. The side surface 2c includes a side surface 21c of the substrate 21 and a side surface 22c of the layer 22. The side surface 2d includes a side surface 21d of the substrate 21 and a side surface 22d of the layer 22. For example, the side surfaces 22a, 22b, 22c, 22d extend to be flush with the side surfaces 21a, 21b, 21c, 21d, respectively.

The substrate 21 is provided above the substrate 11. Examples of the substrate 21 include a semiconductor wafer such as a silicon substrate.

The layer 22 is provided on the surface of the substrate 21. The layer 22 is arranged between the substrate 21 and the layer 12. The layer 22 has a memory cell array 220 and a conductive pad 221.

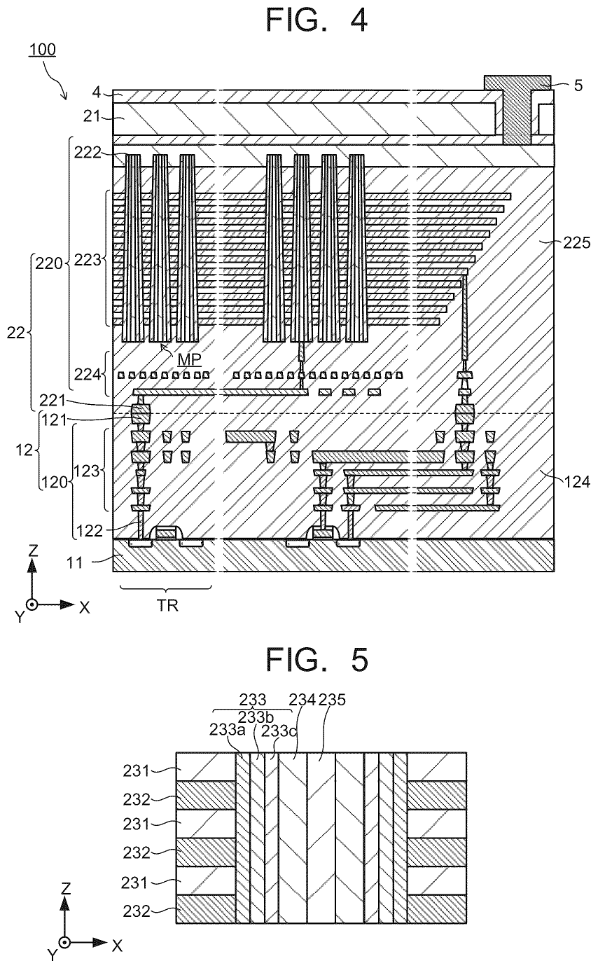

Example structures of the semiconductor substrate 1 and the semiconductor substrate 2 will be further explained with reference to FIG. 4. FIG. 4 is a cross-sectional schematic view illustrating the example structure of the semiconductor chip 100. FIG. 4 illustrates a concrete example of a part of the X-Z cross section illustrated in FIG. 2. FIG. 4 illustrates the memory cell array 220 with part thereof omitted and indicated by a broken line.

The peripheral circuit 120 has a transistor TR on the substrate 11, a conductive layer 122, a multilayer wiring 123, and an interlayer insulating film 124.

The transistor TR is an N-channel field effect transistor or a P-channel field effect transistor. FIG. 1 to FIG. 4 illustrate a plurality of the transistors TR, and the number of the transistors TR is not limited to the number of the transistors TR illustrated in FIG. 1 to FIG. 4. The transistors TR may include the N-channel field effect transistor and the P-channel field effect transistor.

The transistors TR form a CMOS circuit of the peripheral circuit 120, for example. The transistors TR may be electrically isolated from one another by at least one isolator such as Shallow Trench Isolation (STI), for example.

The conductive pad 121 is exposed to the surface of the layer 12. The conductive pad 121 is electrically connected to the peripheral circuit 120 via the multilayer wiring 123 in the layer 12. The conductive pad 121 can be formed from a metal material such as copper, for example. FIG. 1 to FIG. 4 illustrate a plurality of the conductive pads 121, and the number of the conductive pads 121 is not limited to the number illustrated in FIG. 1 to FIG. 4.

The conductive layer 122 includes a contact plug. The multilayer wiring 123 is electrically connected to one of a gate, a source, and a drain of the transistor TR via the conductive layer 122. The conductive layer 122 and the multilayer wiring 123 contain a metal material.

The interlayer insulating film 124 covers the transistor TR, the conductive layer 122, and the multilayer wiring 123. Examples of the interlayer insulating film 124 include an oxide silicon film.

The memory cell array 220 is provided between the substrate 21 and the conductive pad 221. The memory cell array 220 has a conductive layer 222, a stack 223, a memory pillar MP, a multilayer wiring 224, and an interlayer insulating film 225.

The conductive layer 222 is arranged between the substrate 21 and the stack 223. The conductive layer 222 forms a source line of the memory chip, for example. The conductive layer 222 contains a metal material, for example. The conductive layer 222 may not be provided.

The stack 223 has insulating layers and conductive layers, and each insulating layer and each conductive layer are alternately stacked in the Z-axis direction.

The memory pillar MP extends in the Z-axis direction to penetrate in the stack 223 as illustrated in FIG. 4. The memory pillar MP is electrically connected to the conductive layer 222, for example. FIG. 4 illustrates a plurality of the memory pillars MP, and the number of the memory pillars MP is not limited to the number of the memory pillars MP illustrated in FIG. 4. The memory cell array 220 overlaps with the peripheral circuit 120 in the Z-axis direction in FIG. 4, but not limited to this structure, the memory cell array 220 may not overlap with the peripheral circuit 120.

FIG. 5 is a cross-sectional schematic view for explaining the example structure of the memory pillar MP. FIG. 5 illustrates a concrete example of a part of the X-Z cross section illustrated in FIG. 4. FIG. 5 illustrates an insulating layer 231, a conductive layer 232, a memory layer 233, a semiconductor layer 234, and a core insulator 235. The memory pillar MP has the memory layer 233, the semiconductor layer 234, and the core insulator 235.

The insulating layer 231 and the conductive layer 232 form the stack 223. A plurality of the conductive layers 232 form word lines of the memory chip. The insulating layer 231 contains oxide silicon, for example. The conductive layer 232 contains a metal material.

The memory layer 233 has a block insulating film 233a, a charge storage film 233b, and a tunnel insulating film 233c. The block insulating film 233a and the tunnel insulating film 233c contain oxide silicon, for example. The charge storage film 233b contains nitride silicon, for example.

The semiconductor layer 234 penetrates the stack 223 along the Z-axis direction. The semiconductor layer 234 is electrically connected to the conductive layer 222. An outer circumference side surface of the semiconductor layer 234 is surrounded and covered by the memory layer 233. The semiconductor layer 234 contains polycrystalline silicon, for example.

The core insulator 235 is provided on an inner circumference side surface of the semiconductor layer 234. The core insulator 235 extends along the semiconductor layer 234. The core insulator 235 contains oxide silicon, for example. An intersection of the memory pillar MP and the conductive layer 232 functions

as a memory transistor. The memory transistor forms a memory cell of the memory cell array.

The multilayer wiring 224 includes bit lines of the memory chip. The bit line is connected to one of the memory pillars MP via a plug. The multilayer wiring 224 contains a metal material.

The conductive pad 221 is exposed to the surface of the layer 22. The conductive pad 221 is connected to the memory cell array 220 via the multilayer wiring 224. The conductive pad 221 can be formed from a metal material such as copper, for example. FIG. 1 to FIG. 4 illustrate a plurality of the conductive pads 221, and the number of the plurality of conductive pads 221 is not limited to the number illustrated in FIG. 1 to FIG. 4

The conductive pad 221 is bonded to the conductive pad 121. This can electrically connect the memory cell array 220 and the peripheral circuit 120, for example. The interlayer insulating film 225 covers the surface of the substrate 21 and on

the memory pillar MP. The interlayer insulating film 225 covers the conductive layer 222, the stack 223, the memory pillar MP, and the multilayer wiring 224, and is flattered on its surface facing the interlayer insulating film 124. Examples of the interlayer insulating film 225 include an oxide silicon film.

The insulator 3 is in contact with each of the side surfaces 11a to 11d, each of the side surfaces 12a to 12d, each of the side surfaces 21a to 21d, and each of the side surfaces 22a to 22d as illustrated in FIG. 1 to FIG. 3. The insulator 3 covers each of the side surfaces 11a to 11d, each of the side surfaces 12a to 12d, each of the side surfaces 21a to 21d, and each of the side surfaces 22a to 22d. The insulator 3 may cover at least one of the side surfaces 11a to 11d. The insulator 3 may cover an entirety of each of these side surfaces. The insulator 3 contains a molding resin such as an epoxy thermosetting resin represented by an epoxy mold compound (EMC), an underfill resin, or a polyimide resin, for example. The insulator 3 may further contain a filler of a silicon oxide such as oxide silicon.

The insulating layer 4 is provided on the insulator 3 and on the semiconductor substrate 2. The insulating layer 4 covers a surface of the substrate 21, the surface being across the substrate 21 from the memory pillar MP. The insulating layer 4 is in contact with the surface of the insulator 3 and the surface of the substrate 21, for example. The insulating layer 4 contains a polyimide resin, for example. The illustration of the insulating layer 4 is omitted in FIG. 1 for convenience.

The electric conductor 5 is provided on the insulating layer 4. The electric conductor 5 has a function as a pad for inputting/outputting a signal or a voltage to/from an external part. FIG. 1 illustrates a plurality of the electric conductors 5, and the number of the electric conductors 5 is not limited to the number illustrated in FIG. 1. One of the electric conductors 5 penetrates the substrate 21 and the insulating layer 4 and is electrically connected to the memory cell array 220 as illustrated in FIG. 4. Another of the electric conductors 5 may be electrically connected to one source region or drain region of the transistor TR via a contact plug not-illustrated in FIG. 4. The electric conductor 5 can be formed from a metal material such as copper, for example.

As explained above, the semiconductor chip 100 has a structure that the insulator 3 covers at least one of the side surfaces of the semiconductor substrate 1. This can prevent or reduce warpage of the semiconductor chip 100, for example. This can improve the reliability of the semiconductor chip 100.

### Example Method of Manufacturing the Semiconductor Chip 100

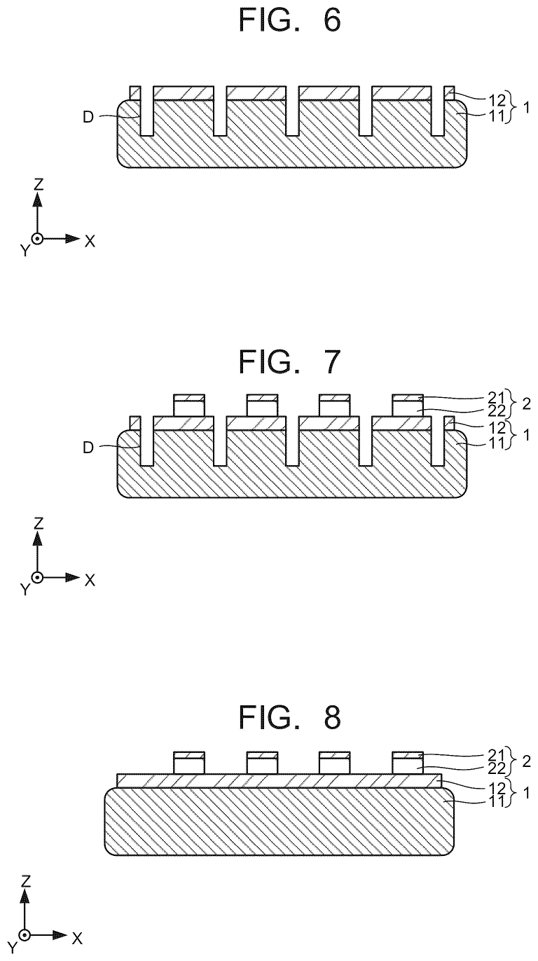

FIG. 6 to FIG. 16 are schematic views for explaining an example method of manufacturing the semiconductor chip 100. Here, a method of manufacturing a plurality of the semiconductor chips 100 through the same steps will be explained below. FIG. 6 to FIG. 11 and FIG. 13 to FIG. 16 illustrate a part of the X-Z cross section of the semiconductor substrate 1. FIG. 12 illustrates a part of the X-Y plane of the semiconductor substrate 1.

As illustrated in FIG. 6, a groove D is formed in the semiconductor substrate 1. The semiconductor substrate 1 can be manufactured by preparing the substrate 11 and forming the layer 12 onto the substrate 11 through any of the known methods, for example. The layer 12 has a plurality of the peripheral circuits 120, and each of the peripheral circuits 120 is provided for each semiconductor chip 100 to be manufactured. The groove D can be formed through blade dicing, laser grooving, plasma dicing, or etching, for example.

The groove D forms a grid pattern on and along the surface of the semiconductor substrate 1, for example. The depth of the groove D (a length in the Z-axis direction of the groove D from the surface of the semiconductor substrate 1 to an inner bottom surface of the groove D) is equal to or more than 20 mm and equal to or less than ⅓ of a thickness of the unprocessed substrate 11 (a length in the Z-axis direction of the unprocessed substrate 11), for example. The adjustment of the depth of the groove D to the above range, can prevent or reduce the warpage of the substrate 11 after manufacturing the semiconductor chip 100, for example. This improve the reliability of the semiconductor chip 100.

Next, as illustrated in FIG. 7, the semiconductor substrate 2 is joined to the semiconductor substrate 1. For example, the plurality of the semiconductor substrates 2 can be joined to the surface of the semiconductor substrate 1 by bringing the semiconductor substrates 2 into close contact with the semiconductor substrate 1 such that the layers 22 face the layer 12. The semiconductor substrate 2 can be manufactured by preparing the substrate 21 and forming the layer 22 on the substrate 21 through any of the known methods, for example. Each semiconductor substrate 2 is joined for each semiconductor chip 100 to be manufactured. In this specification, the joining means bringing the semiconductor substrate 1 and the semiconductor substrate 2 into close contact with each other before a heating treatment. The semiconductor substrate 2 is joined to a region provided on the surface of the semiconductor substrate 1 and surrounded by the groove D along the surface of the semiconductor substrate, for example.

Thereafter, the semiconductor substrate 1 and the semiconductor substrate 2 are bonded. The bonding in this specification means firmly fixing the semiconductor substrate 1 and the semiconductor substrate 2. The semiconductor substrate 1 and the semiconductor substrate 2 are bonded by the heating treatment, for example. The conductive pad 121 and the conductive pad 221 are directly bonded by element diffusion between metals, Van der Waals force, recrystallization by cubical expansion or melting, for example. Further, the semiconductor substrate 1 and the semiconductor substrate 2 can be bonded by direct bonding by a chemical reaction such as element diffusion, Van der Waals force, dehydration condensation, or polymerization between the interlayer insulating film 124 and the interlayer insulating film 225, or by bonding between a metal and an insulating layer. These bondings are also called hybrid bonding. The bonding interface between the semiconductor substrates 1 and 2, may not be clearly observed after the heating treatment.

The joining and bonding of the semiconductor substrate 2 to the semiconductor substrate 1 after forming the groove D, can prevent or reduce the breakage of the semiconductor substrate 2 caused by forming the groove D, for example. Not limited to the above, as illustrated in FIG. 8, the semiconductor substrate 2 is joined and bonded to the semiconductor substrate 1 before forming the groove D, and then the groove D may be formed on a region provided on the surface of the semiconductor substrate 1 and surrounding the semiconductor substrate 2 along the surface of the semiconductor substrate 1, for example. The joining and bonding of the semiconductor substrate 2 to the semiconductor substrate 1 before forming the groove D, can prevent or reduce dust produced by forming the groove D from remaining between the semiconductor substrate 1 and the semiconductor substrate 2, for example. The dust decreases the reliability of the semiconductor chip 100, for example.

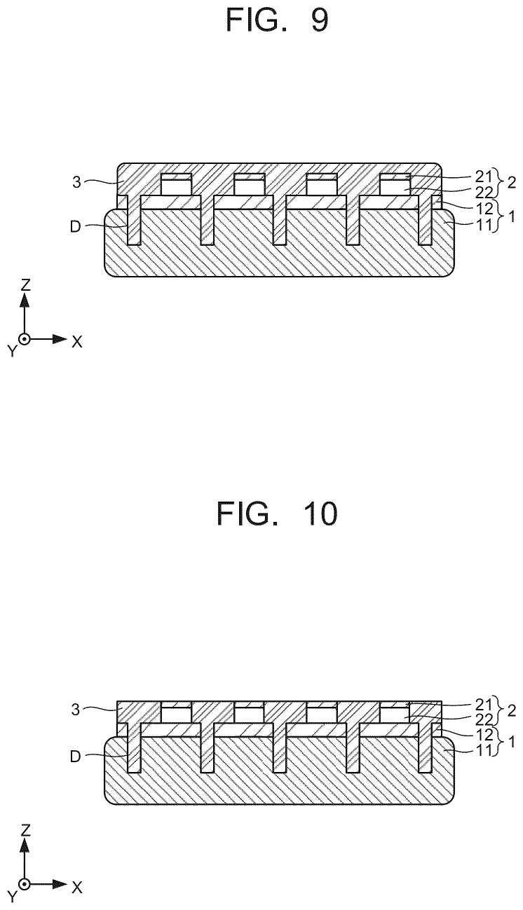

Next, as illustrated in FIG. 9, the insulator 3 is formed. The insulator 3 is formed in a manner to fill the groove D and cover the semiconductor substrate 2. Accordingly, the insulator 3 is in contact with the inner bottom surface and the inner side surface of the groove D. An example of the insulator 3 can be formed from a material applicable to the insulator 3 and formed by a molding method such as a transfer molding method, a compression molding method, or an injection molding method.

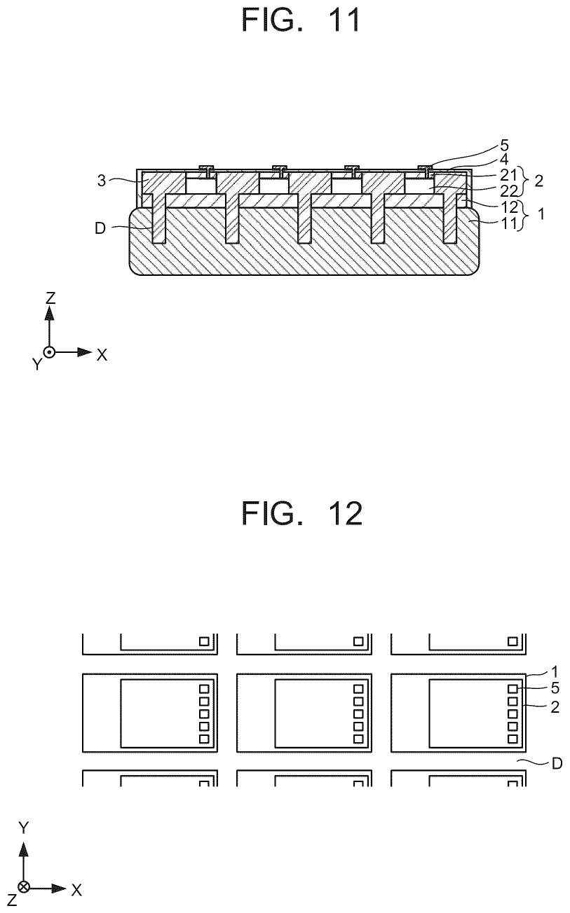

Next, as illustrated in FIG. 10, the surface opposite to the layer 22 of the substrate 21 is exposed by partly removing the insulator 3 in the thickness direction (Z-axis direction). The insulator 3 can be partly removed by chemical mechanical polishing (CMP), for example. Further, the substrate 21 may be completely removed so that the layer 22 is exposed. In this case, the substrate 21 can be completely removed by stopping the CMP after the layer 22 is exposed.

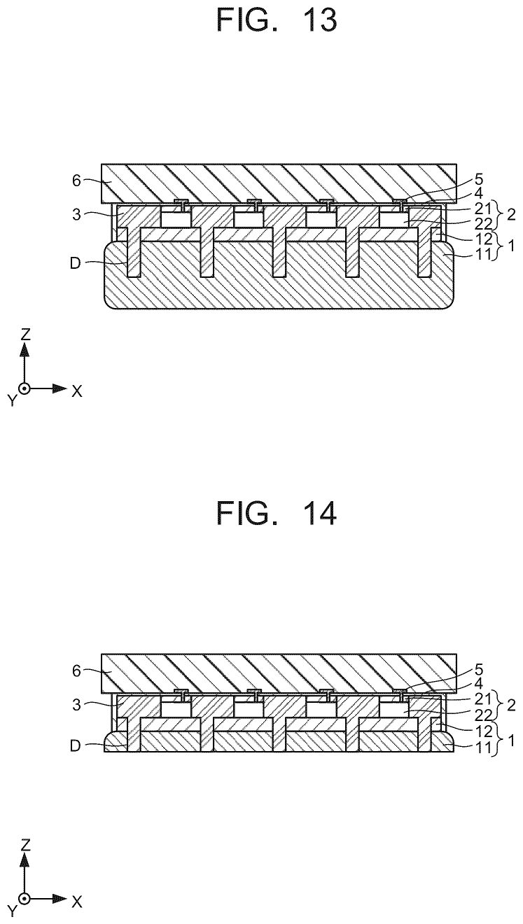

Next, as illustrated in FIG. 11, the insulating layer 4 and the electric conductor 5 are formed. The insulating layer 4 is formed in a manner to form an opening penetrating the substrate 21 and reaching the layer 22 and then cover the semiconductor substrate 2 and the insulator 3, for example. The insulating layer 4 can be formed through the chemical vapor deposition method (CVD) or the coating method, for example. The electric conductor 5 is formed by forming a conductive film in the opening, for example. The conductive film can be formed using sputtering, for example. When the substrate 21 is completely removed, the insulating layer 4 and the electric conductor 5 are formed directly on the layer 22.

FIG. 12 illustrates a part of the X-Y plane of the semiconductor substrate 1 and the semiconductor substrate 2 after the formation of the electric conductor 5. The illustration of the insulator 3 and the insulating layer 4 is omitted in FIG. 12 for convenience. As illustrated in FIG. 12, the semiconductor substrate 2, the electric conductor 5, and the like are formed in each of the regions surrounded by the groove D of the semiconductor substrate 1.

Next, as illustrated in FIG. 13, a tape 6 is stuck on the surface opposite to the surface on the semiconductor substrate 2 of the insulating layer 4 and the surface opposite to the surface on the semiconductor substrate 2 of the electric conductor 5. Examples of the tape 6 include a back grinding tape.

Next, as illustrated in FIG. 14, the region provided on the insulator 3 and filled in the groove D is partly exposed from the semiconductor substrate 1 by partly grinding the semiconductor substrate 1 in the thickness direction (Z-axis direction) from the surface opposite to the surface on the semiconductor substrate 2 of the semiconductor substrate 1 through back grinding. This grinding also enable partly exposing the insulator 3 from the surface opposite to the surface on the semiconductor substrate 2 of the semiconductor substrate 1 to prevent or reduce the warpage of the semiconductor substrate 1. This can improve the reliability of the semiconductor chip 100. The tape 6 is unstuck from the insulating layer 4 and the electric conductor 5 after the back grinding.

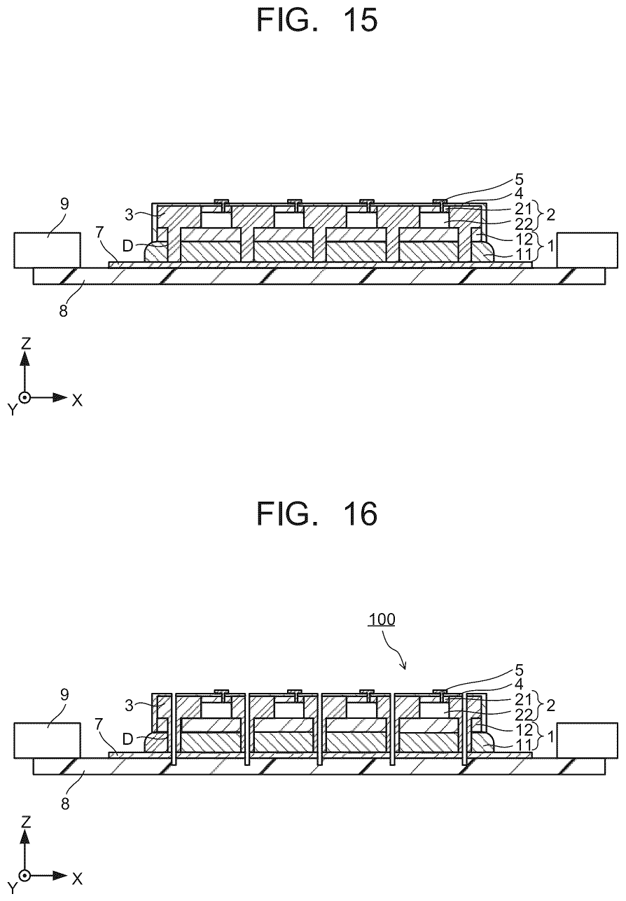

Next, as illustrated in FIG. 15, the opposite surface of the semiconductor substrate 1 is stuck to a dicing tape 8 via an adhesive layer 7 therebetween. Examples of the adhesive layer 7 include a die attach film. A periphery of the dicing tape 8 is fixed to a wafer ring 9. The semiconductor substrate 1 is stuck to the dicing tape 8 in a manner to overlap with a hollow portion of the wafer ring 9.

Next, as illustrated in FIG. 16, the semiconductor substrate 1 and the insulator 3 are divided along the groove D. The semiconductor substrate 1 and the insulator 3 can be divided through blade dicing, laser dicing, or water jet, for example. In particular, the blade dicing is preferable due to enable easily processing the semiconductor substrate 1 and the insulator 3. The semiconductor substrate 1 and the insulator 3 are divided (individualized) for each semiconductor chip 100.

When the semiconductor substrate 1 and the insulator 3 are divided along the groove D through the blade dicing, the width of the groove D (a length of the groove D in the X-axis direction or the Y-axis direction) is preferably larger than the thickness of a dicing blade. This can divide the semiconductor substrate 1 along the insulator 3 without the dicing blade being in contact with the semiconductor substrate 1.

Thereafter, each semiconductor chip 100 is detached from the adhesive layer 7 and the dicing tape 8. The above steps can manufacture the semiconductor chip 100.

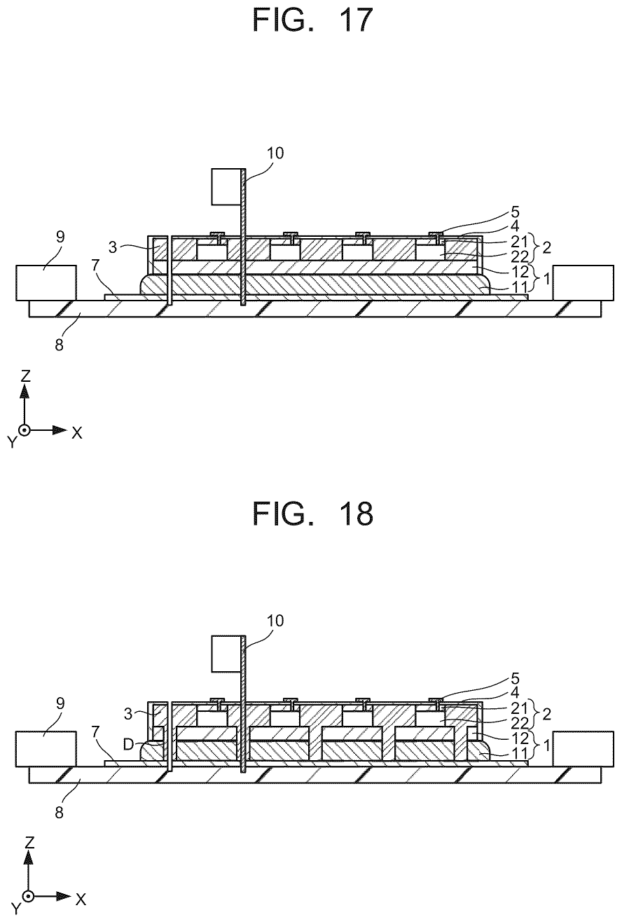

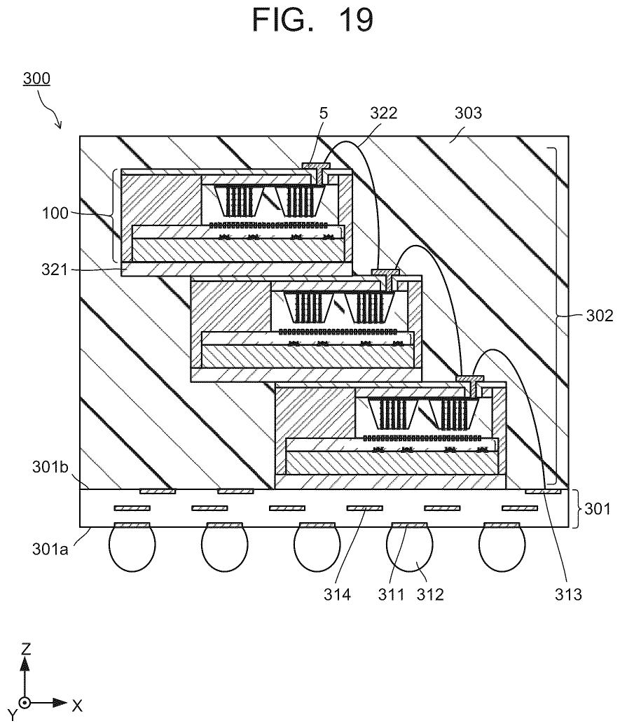

Here, a difference between a case of forming the groove D and a case of not forming the groove D in the example method of manufacturing the semiconductor chip 100 will be explained. FIG. 17 and FIG. 18 are schematic views for explaining the difference between the case of forming the groove D and the case of not forming the groove D. FIG. 17 and FIG. 18 illustrate an appearance of dividing the semiconductor substrate 1 through blade dicing and illustrate the X-Z cross section of the semiconductor substrate 1 and the semiconductor substrate 2.

In the case of not forming the groove D, as illustrated in FIG. 17, a dicing blade 10 passes through the interface between the semiconductor substrate 1 and the insulator 3, and the dicing blade 10 divides the semiconductor substrate 1 while being in contact with both of the semiconductor substrate 1 and the insulator 3. This may cause defects such as chipping that causes cracking or chips at a cut surface, peeling of the insulator 3 at the interface between the layer 12 and the insulator 3, and the like. The above defects are more likely to occur, for example, when two different hard layers such as the semiconductor substrate 1 and the insulator 3 are cut at a time. Further, the defects occur inside the semiconductor chip 100, and are therefore difficult to find by the inspection of the semiconductor chip 100 after the division.

In contrast to the above case, the method in the embodiment includes forming the groove D in the semiconductor substrate 1 and filling the groove D with the insulator 3, to enables cutting only the insulator 3 using the dicing blade 10 without the dicing blade 10 being contact with the semiconductor substrate 1 to cut the semiconductor substrate 1, as illustrated in FIG. 18. This can prevent or reduce the defects such as chipping and peeling of the insulator 3. This can improve the reliability of the semiconductor chip 100. The case of blade dicing is explained in FIG. 17 and FIG. 18, and the above also applies to a case of dividing the semiconductor substrate 1 by other methods.

### Example Structure of a Semiconductor Package

As another example of the semiconductor device in the embodiment, an example of a semiconductor package having the semiconductor chip 100 will be explained. FIG. 19 is a schematic view illustrating an example structure of the semiconductor package. FIG. 19 illustrates the X-Z cross section.

A semiconductor package 300 has a wiring board 301, a chip stack 302, and a sealing insulator 303.

The wiring board 301 has a conductive pad 311 provided on a surface 301a, an external connection terminal 312 provided on the surface of the conductive pad 311, a conductive pad 313 provided on a surface 301b opposite to the surface 301a, and an internal wiring 314 which electrically connects the conductive pad 311 and the conductive pad 313. Examples of the wiring board 301 include a printed wiring board (PWB). FIG. 19 illustrates a plurality of the conductive pads 311, a plurality of the external connection terminals 312, a plurality of the conductive pads 313, and a plurality of the internal wirings 314, and the numbers of them are not limited to the numbers of them illustrated in FIG. 19.

The external connection terminal 312 can be formed from gold, copper, or solder, for example. The external connection terminal 312 may be formed from a tin-silver based or tin-silver-copper based lead-free solder, for example. Further, the external connection terminal 312 may be formed using a stack of a plurality of metal materials. FIG. 19 illustrates the external connection terminal 312 formed using a conductive ball.

The conductive pad 313 is connected to the external connection terminal 312 via the internal wiring 314 and the conductive pad 311 of the wiring board 301. The conductive pad 311 and the conductive pad 313 contain at least one metal element selected from copper, gold, palladium, and nickel, for example. The conductive pad 311 and the conductive pad 313 may be formed by forming a plating film containing the above material, for example, by an electrolytic plating method or an electroless plating method.

The chip stack 302 is provided above the surface 301b of the wiring board 301. The chip stack 302 has the semiconductor chip 100, an adhesive layer 321, and a bonding wire 322. FIG. 19 illustrates the chip stack 302 having a plurality of the semiconductor chips 100, and the number of the semiconductor chips 100 is not limited to the number illustrated in FIG. 19. The explanation of the above embodiment can be used as appropriate for the other explanation of the semiconductor chip 100.

The semiconductor chips 100 are stacked in order above the surface 301b of the wiring board 301 via the respective adhesive layers 321. Examples of the adhesive layer 321 include a die attach film. FIG. 19 illustrates three semiconductor chips 100 stacked in tiers on top of each other above the surface 301b. In other words, the semiconductor chips 100 are tiered on top of each other and partly overlap with each other.

The electric conductor 5 of each semiconductor chip 100 is connected to each conductive pad 313 via the corresponding bonding wire 322. The bonding wire 322 contains at least one metal element selected from gold, silver, copper, and palladium, for example. One of the semiconductor chips 100 is attached to another of the semiconductor chips 100 via the adhesive layer 321, for example. The semiconductor chip 100 at the lowermost tier may be attached to the surface 301b or a spacer via the adhesive layer 321, for example.

The sealing insulator 303 is provided in a manner to cover the chip stack 302 to seal the chip stack 302. The sealing insulator 303 contains an inorganic filler such as oxide silicon (SiO₂) and a resin such as an epoxy thermosetting resin, and can be formed from a sealing resin made by mixing the inorganic filler with a resin such as an organic resin and through a molding method such as a transfer molding method, a compression molding method, or an injection molding method, for example.

The semiconductor package 300 may have a conductive shield on the surface of the sealing insulator 303. The conductive shield covers at least a part of a side surface of the wiring board 301 and the sealing insulator 303. The conductive shield can be formed through sputtering, for example. The conductive shield is preferably formed of a low electric resistivity metal layer, which is a metal layer made of copper, SUS, or nickel, in terms of preventing leakage of an unnecessary electromagnetic wave radiated from the semiconductor chip 100 inside the sealing insulator 303 and the internal wiring of the wiring board 301. The thickness of the conductive shield is preferably set based on its electric resistivity. The conductive shield may be connected to the wiring connected to the external connection terminal 312 such as a ground terminal by partly exposing the via in the wiring board 301 and bringing it into contact with the conductive shield.

As explained above, the semiconductor package in the embodiment has the semiconductor chip 100 in which defects such as warpage, chipping, and peeling of the insulator 3 are prevented or reduced. This can improve the reliability of the semiconductor package.

While certain embodiments of the present invention have been described above, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first substrate;
a second substrate provided above the first substrate, the second substrate being smaller in area than the first substrate when the second substrate is viewed from above;
a first layer provided between the first substrate and the second substrate and having a first conductive pad;
a second layer provided between the first layer and the second substrate and having a second conductive pad bonded to the first conductive pad; and
an insulator covering each of at least one side surface of the first substrate and at least one side surface of the second substrate.

2. The device according to claim 1, wherein:
the first substrate has a first side surface, a second side surface, a third side surface, and a fourth side surface; and
the insulator covers each of the first to fourth side surfaces.

3. The device according to claim 1, further comprising:
a wiring board; and
a semiconductor chip provided on the wiring board, wherein
the semiconductor chip has the first substrate, the first layer, the second substrate, the second layer, and the insulator.

4. The device according to claim 1, wherein
the insulator contains a molding resin, an underfill resin, or a polyimide resin.

5. The device according to claim 1, wherein
the insulator contains a silicon oxide.

6. The device according to claim 4, wherein
the insulator contains a silicon oxide.

7. A semiconductor device comprising:
a first semiconductor substrate including a peripheral circuit;
a second semiconductor substrate bonded to the first semiconductor substrate and including a memory cell array connected to the peripheral circuit, the second semiconductor substrate being smaller in area than the first semiconductor substrate when the second semiconductor substrate is viewed from above; and
an insulator provided on the first and second semiconductor substrates and surrounding the second semiconductor substrate, wherein
a first semiconductor substrate has a first side, a second side, a third side and a fourth side,
a second semiconductor substrate has a fifth side, a sixth side, a seventh side and a eighth side, and
the insulator covers each of the first to eighth sides.

8. The device according to claim 7, wherein
the insulator contains a molding resin, an underfill resin, or a polyimide resin.

9. The device according to claim 7, wherein
the insulator contains a silicon oxide.

10. The device according to claim 7, wherein
the insulator covers an entirety of each of the first to eighth sides.

11. A method of manufacturing a semiconductor device, comprising:
forming a groove on a surface of a first semiconductor substrate, the first semiconductor substrate having a first substrate and a first layer, the first layer having a first conductive pad provided on the first substrate, the groove extending into the first substrate through the first layer;
joining a second semiconductor substrate and the surface of the first semiconductor substrate, the second semiconductor substrate having a second substrate and a second layer, the second semiconductor substrate being smaller in area than the first semiconductor substrate when the second semiconductor substrate is viewed from above, the second layer having a second conductive pad provided on the second substrate;
bonding the first conductive pad and the second conductive pad;
forming an insulator filling the groove and covering the second semiconductor substrate; and
dividing the insulator through the groove to divide the first semiconductor substrate.

12. The method according to claim 11, wherein
the groove is formed so as to surround the second semiconductor substrate along the surface of the first semiconductor substrate.

13. The method according to claim 11, wherein
the groove is formed before joining the second semiconductor substrate and the surface of the first semiconductor substrate.

14. The method according to claim 11, wherein
the groove is formed after joining the second semiconductor substrate and the surface of the first semiconductor substrate.

15. The method according to claim 11, wherein
the groove is formed using blade dicing, laser grooving, plasma dicing, or etching.

16. The method according to claim 11, wherein
the first semiconductor substrate and the insulator are divided using blade dicing, laser grooving, or water jet.

17. The method according to claim 11, wherein
the first substrate has:
a first surface on the first layer; and
a second surface opposite to the first surface of the first substrate,
the method further comprising
partly removing the first substrate in a thickness direction of the first substrate to expose the insulator from the second surface, before dividing the insulator through the groove.

18. The method according to claim 17, wherein
the insulator is divided not through any interface between the first semiconductor substrate and the insulator.

19. The method according to claim 11, wherein
the second substrate has:
a third surface on the second layer; and
a fourth surface opposite to the third surface of the second substrate,
the method further comprising
partly or completely removing the insulator in a thickness direction of the second substrate to expose the second substrate or the second layer from the insulator, before dividing the insulator through the groove.

20. The method according to claim 11, wherein
a plurality of the second semiconductor substrates is bonded to the surface of the first semiconductor substrate, and
the first semiconductor substrate and the insulator are divided for each second semiconductor substrate.
